(19) United States
(12) Patent Application Publication
(10) Pub. No.: US 2026/0150338 A1
(43) Pub. Date: May 28, 2026

(54) SEMICONDUCTOR DEVICE AND METHOD OF FABRICATION THEREOF

(71) Applicant: INTERNATIONAL BUSINESS MACHINES CORPORATION, ARMONK, NY (US)

(72) Inventors: Reinaldo Vega, Mahopac, NY (US); Minhaz Abedin, Delmar, NY (US); Mahender Kumar, Clifton Park, NY (US); Xiaoming Yang, Clifton Park, NY (US); Ravikumar Ramachandran, Pleasantville, NY (US)

(21) Appl. No.: 18/957,577

(22) Filed: Nov. 22, 2024

(51) Int. Cl. H01L 29/417; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/254

(57) ABSTRACT

A semiconductor device includes a substrate having a frontside, a backside, and a transistor that includes a gate region, a first source/drain region of a first depth into the substrate, and a second source/drain region of a second depth into the substrate. The semiconductor device further includes a backside contact (BC) region extending from the backside into the substrate and electrically connected to the first source/drain region. The semiconductor device further includes a backside partial diffusion break (BPDB) region that includes a non-conducting material, extending from the backside into the substrate and distinct from the first source/drain region.

### BACKGROUND

### Technical Field

The present disclosure generally relates to semiconductor devices, and more particularly, to structures and methods for implementing backside contacts and diffusion breaks to enhance electrical connectivity and isolation in semiconductor devices.

### Description of the Related Art

Semiconductor devices are essential components in modern electronic systems and are used in applications ranging from consumer electronics to advanced computing. As technology advances, efforts are made to improve the performance and integration density of the semiconductor devices. Achieving higher speeds, lower power consumption, and increased functionality often involves reducing the physical size and optimizing electrical characteristics of the semiconductor devices.

Scaling semiconductor devices involves reducing the dimensions while increasing the transistor count to meet the demands of modern electronics. Backside power distribution networks (BSPDN) have been developed to facilitate the reduction of device size and increase in transistor count by utilizing the backside of the semiconductor substrate for routing power signals. Implementing backside power distribution alleviates congestion on the frontside of the substrate, allowing more efficient use of space. Direct backside contacts (DBC) enable BSPDN by providing electrical connections from the backside of the substrate to active regions within the device, contributing to efficient power distribution and further miniaturization of the semiconductor devices.

Source/drain regions are doped areas within the substrate that serve as terminals of transistors, controlling the flow of electric current. Managing the depth and profile of the source/drain regions is essential for controlling short-channel effects, especially as device dimensions shrink. Employing shallow source/drain regions achieves specific electrical characteristics suitable for advanced device operation.

### SUMMARY

According to an aspect of the disclosure, a semiconductor device includes a substrate having a frontside, a backside, and a transistor. The transistor that includes a gate region, a first source/drain region of a first depth into the substrate, and a second source/drain region of a second depth into the substrate. The semiconductor device further includes a backside contact (BC) region extending from the backside into the substrate and electrically connected to the first source/drain region. The semiconductor device further includes a backside partial diffusion break (BPDB) region that includes a non-conducting material, extending from the backside into the substrate and distinct from the first source/drain region.

According to an embodiment, the semiconductor device further includes a gate region positioned between a pair of source/drain regions, forming a semiconductor transistor structure. According to another embodiment of the disclosure, a method of fabricating a semiconductor device includes providing a substrate having a frontside and a backside, with a thickness of the substrate measured from the frontside to the backside, and forming several source/drain regions extending from the frontside into the substrate to a depth less than the thickness of the substrate. The method involves thinning the substrate from the backside to reduce the thickness. The method further includes forming one or more backside partial diffusion break (BPDB) regions at the backside of the substrate by forming one or more BPDB openings at the backside, etching through the BPDB openings to remove a portion of the substrate, including a bottom portion of one or more second source/drain regions of the several source/drain regions and filling the etched BPDB region with a non-conductive material.

The method further includes forming one or more backside contact (BC) region at the backside of the substrate by forming one or more BC openings at the backside, etching through the BC openings to remove a portion of the substrate, including a bottom portion of one or more first source/drain region that is distinct from the second source/drain region of the several source/drain regions and filling the etched BC region with a conductive material.

In one embodiment, the method of forming the at least one BPDB opening and the at least one BC opening further includes creating at least one etching pattern on the backside of the substate by placing a pattern mask, using a self-aligned etching process without the pattern mask, or a combination thereof.

In an alternate embodiment, forming the BPDB region involves depositing a non-conductive liner on the etched BPDB region and filling the etched BPDB region coated with the non-conductive liner using the conductive material. In some embodiments, the BPDB region may be extended deeper into the substrate than the BC is extended into the substrate. Additionally, the BC region may be positioned adjacent to the BPDB region within the substrate to facilitate self-alignment with the first source/drain region during etching.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 depicts a cross-sectional view of a semiconductor device in accordance with an illustrative embodiment.

FIG. 2A depicts a cross-sectional view of a semiconductor device showing a plurality of source/drain regions in accordance with an illustrative embodiment.

FIG. 2B depicts a cross-sectional view of the semiconductor device showing the substrate after the thinning process in accordance with an illustrative embodiment.

FIG. 2C depicts a cross-sectional view of the semiconductor device showing an etching pattern mask formed on the backside of the substrate in accordance with an illustrative embodiment.

FIG. 2D depicts a cross-sectional view of the semiconductor device showing a backside partial diffusion break (BPDB) opening in accordance with an illustrative embodiment.

FIG. 2E depicts a cross-sectional view of the semiconductor device showing the BPDB opening filled with a non-conductive material in accordance with an illustrative embodiment.

FIG. 2F depicts a cross-sectional view of the semiconductor device showing the BC openings formed on the backside of the substrate through a self-aligned etching process without the pattern mask in accordance with an illustrative embodiment.

FIG. 2G depicts a cross-sectional view of the semiconductor device showing a polished backside surface of the substrate with the BC openings filled with the conductive material in accordance with an illustrative embodiment.

FIG. 3A depicts a cross-sectional view of a semiconductor device showing a plurality of source/drain regions in accordance with an alternate embodiment.

FIG. 3B depicts a cross-sectional view of the semiconductor device showing the substrate after a thinning process in accordance with an alternate embodiment.

FIG. 3C depicts a cross-sectional view of the semiconductor device showing an etching pattern mask formed on the backside of the substrate in accordance with an alternate embodiment.

FIG. 3D depicts a cross-sectional view of the semiconductor device showing a backside partial diffusion break (BPDB) opening in accordance with an alternate embodiment.

FIG. 3E depicts a cross-sectional view of the semiconductor device showing the BPDB opening filled with a non-conductive material in accordance with an alternate embodiment.

FIG. 3F depicts a cross-sectional view of the semiconductor device showing an etching pattern mask formed on the backside of the substrate to define one or more BC openings at the backside of the substrate in accordance with an illustrative embodiment.

FIG. 3G depicts a cross-sectional view of the semiconductor device showing the BC openings formed on the backside of the substrate in accordance with an illustrative embodiment.

FIG. 3H depicts a cross-sectional view of the semiconductor device showing a polished backside surface of the substrate with the BC openings filled with the conductive material and the BPDB opening filled with the non-conductive material in accordance with an illustrative embodiment.

FIG. 4A depicts a cross-sectional view of a semiconductor device showing a plurality of source/drain regions in accordance with an alternate embodiment.

FIG. 4B depicts a cross-sectional view of the semiconductor device showing the substrate after a thinning process in accordance with an alternate embodiment.

FIG. 4C depicts a cross-sectional view of the semiconductor device showing an etching pattern mask formed on the backside of the substrate in accordance with an alternate embodiment.

FIG. 4D depicts a cross-sectional view of the semiconductor device showing a backside partial diffusion break (BPDB) opening in accordance with an alternate embodiment.

FIG. 4E depicts a cross-sectional view of the semiconductor device showing the BPDB opening filled with a non-conductive liner and a conductive material in accordance with an alternate embodiment.

FIG. 4F depicts a cross-sectional view of the semiconductor device showing an etching pattern mask formed on the backside of the substrate to define one or more BC openings at the backside of the substrate in accordance with an illustrative embodiment.

FIG. 4G depicts a cross-sectional view of the semiconductor device showing the BC openings formed on the backside of the substrate in accordance with an illustrative embodiment.

FIG. 4H depicts a cross-sectional view of the semiconductor device showing a polished backside surface of the substrate with the BC openings filled with the conductive material and the BPDB opening filled with the non-conductive liner and the conductive material in accordance with an illustrative embodiment.

FIG. 5A depicts a cross-sectional view of a semiconductor device showing a plurality of source/drain regions in accordance with an alternate embodiment.

FIG. 5B depicts a cross-sectional view of the semiconductor device showing one or more BC openings formed at the backside of the substrate using an etching pattern mask in accordance with an illustrative embodiment.

FIG. 5C depicts a cross-sectional view of the semiconductor device showing the BC openings filled with a conductive material in accordance with an alternate embodiment.

FIG. 5D depicts a cross-sectional view of the semiconductor device showing a backside partial diffusion break (BPDB) opening formed using a self-aligned etching process in accordance with an alternate embodiment.

FIG. 5E depicts a cross-sectional view of the semiconductor device showing a backside surface of the substrate with the BC openings filled with the conductive material and the BPDB opening filled with the non-conductive material in accordance with an illustrative embodiment.

FIG. 6A depicts a cross-sectional view of a semiconductor device showing a plurality of source/drain regions in accordance with an alternate embodiment.

FIG. 6B depicts a cross-sectional view of the semiconductor device showing one or more BC openings formed at the backside of the substrate using an etching pattern mask in accordance with an illustrative embodiment.

FIG. 6C depicts a cross-sectional view of the semiconductor device showing the BC openings filled with a conductive material in accordance with an alternate embodiment.

FIG. 6D depicts a cross-sectional view of the semiconductor device showing the substrate recessed at the backside with one or more offset spacers covering a portion of the BC openings filled with the conductive material in accordance with an alternate embodiment.

FIG. 6E depicts a cross-sectional view of the semiconductor device showing a backside partial diffusion break (BPDB) opening formed on the substrate that is recessed at the backside using a self-aligned etching process in accordance with an alternate embodiment.

FIG. 6F depicts a cross-sectional view of the semiconductor device showing the BC openings filled with the conductive material and one or more offset spacers covering a portion thereof and the BPDB opening filled with the non-conductive material in accordance with an illustrative embodiment.

FIG. 7 depicts a flow diagram showing the steps for fabricating a semiconductor device, in accordance with one embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below”, or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

The concepts herein relate to semiconductor devices and fabrication methods that enhance electrical connectivity and isolation through the implementation of backside contacts (BC) and backside partial diffusion breaks (BPDB). Integrating BCs with shallow source/drain regions, which are necessary for controlling short-channel effects in scalable semiconductor devices, may result in shorts with the gate electrode or other critical components when forming BCs through etching from a backside of a substrate. Using deeper source/drain regions to reduce the risk of shorts can increase leakage currents due to enhanced bulk short-channel effects, thereby degrading device performance.

The illustrative embodiments provide a semiconductor device that allows for optimal alignment of BCs with deep source/drain regions while incorporating BPDBs to suppress parasitic leakage. The BPDBs, provided between the BCs and fully or partially filled with dielectric material, effectively reduce the junction depth of source/drain regions not connected to a BC region, thus suppressing parasitic leakage. Additionally, the BPDBs enable partial self-alignment of BCs without the need for placeholders under source/drain epitaxial layers. Therefore, combining BCs with BPDBs minimizes the risk of shorts and leakage currents, enabling efficient power distribution and improved device reliability without introducing excessive complexity or manufacturing costs.

In embodiments, a semiconductor device comprises a substrate having a frontside and a backside. The semiconductor device further includes a transistor comprising a gate region, a first source/drain region of a first depth into the substrate, and a second source/drain region of a second depth into the substrate. The semiconductor device includes a backside contact (BC) region extending from the backside into the substrate and electrically connected to the first source/drain region, and a backside partial diffusion break (BPDB) region comprising a non-conducting material, extending from the backside into the substrate and distinct from the first source/drain. This configuration of the semiconductor device enhances device performance by enabling efficient electrical connections while minimizing interference between source and drain regions.

In embodiments, the semiconductor device has a first source/drain region with a first depth. The first depth is not equal to the second depth of the second source/drain region, allowing for optimized electrical performance and reduced leakage current by tailoring the source/drain regions to specific operational requirements.

In embodiments, the BPDB region displaces at least a bottom portion of the second source/drain region. This reduces the junction depth of the second source/drain region, thus reducing parasitic leakage between the first and second source/drain regions by reducing charge sharing between the gate and the second source/drain region.

In embodiments, the BPDB region displaces at least a bottom portion of the substrate under the gate and in between the first and second source/drain regions. This reduces the substrate thickness between the first and second source/drain regions which, in turn, reduces sidewall access to the substrate for each of the first and second source/drain regions, thus reducing parasitic leakage by reducing charge sharing between the gate and the source/drain regions.

In embodiments, the BC region further includes a doped region. The doped region is of the same conductivity type as the first source/drain region located along at least a portion of the interface between the BC region and the first source/drain region. The effect of the doped region is two-fold. First, additional dopants at the interface between the BC region and the first source/drain region will reduce contact resistance between the BC region and the first source/drain region. Second, if the doped region also extends along the sidewall of the BC region, then the apparent contact area is increased, thus further reducing contact resistance.

In embodiments, the BPDB region further includes a “counterdoped” region. The “counterdoped” region is of a different conductivity type as the second source/drain region located along at least a portion of the perimeter of the BPDB region. The effect of the “counterdoped” region is to create a larger potential barrier between the substrate and the second source/drain region, thus reducing parasitic leakage between the first and second source/drain regions.

In embodiments, the BC region is formed adjacent to the BPDB region within the substrate. This enables direct self-alignment of the BC region relative to the BPDB boundary, or vice versa, thus reducing process complexity.

In embodiments, the BC region and BPDB region are separated by a non-conducting spacer region. The separation is along at least a portion of the sidewalls of both the backside contact region and the BPDB region. This also enables self-alignment of the BC region relative to the BPDB boundary, or vice versa, albeit with an offset. This offset may serve two functions. First, it provides margin to assure the first source/drain region is not partially etched by the BPDB region, in embodiments where the BC region is formed before the BPDB region. Second, it reduces the size of the BC opening, which may be leveraged to increase the contact area of the BC region.

In embodiments, the BPDB region comprises a conducting material. The conductive material can be electrically isolated from the substrate and second source/drain regions by the non-conducting material. This conducting material can act as a backside gate. It may have a workfunction which is either toward the conduction or valence band edge of the substrate. The effect of this structure is to electrostatically increase the potential barrier between the substrate and the second source/drain region, thus reducing parasitic leakage. An additional effect of this structure is to place an electrically isolated thermal conductor (with a thermal conductivity higher than that of the substrate) closer to the second source/drain region, thus reducing self-heating effects.

In embodiments, the BPDB region includes at least one additional non-conducting material. This allows for material stack optimization throughout the BPDB region. For instance, one non-conducting material may exist as a thin liner along the BPDB periphery, to reduce interface charge, while a second non-conducting material may exist within the remainder of the BPDB opening, which may have less stringent process limitations in terms of material deposition or which may have a lower dielectric constant.

In embodiments, the second source/drain region is electrically connected to a metallization layer along the frontside of the substrate. This separates signal routing connections from power routing connections. For example, if the backside metallization stack is purposed primarily for power distribution, then the BC connects to the first source/drain region to deliver power, while the second source/drain region connects to the frontside for signal routing to a frontside metallization stack.

In embodiments, a method of fabricating a semiconductor device includes providing a substrate that has a frontside, a backside, and a plurality of source/drain regions extending from the frontside into the substrate to a depth less than a thickness of the substrate. The thickness of the substrate is measured from the frontside to the backside. The method includes thinning the substrate from the backside to reduce the thickness of the substrate, forming at least one backside partial diffusion break (BPDB) region at the backside of the substrate by forming at least one BPDB opening, and etching through the at least one BPDB opening to remove a portion of the substrate, including a bottom portion of at least one second source/drain region of the plurality of source/drain regions to form at least one etched BPDB region. At least one etched BPDB region fills at least partially with a non-conductive material, and forming at least one backside contact (BC) region at the backside of the substrate. The forming of the at least one BC may be performed by etching through the at least one DBC opening to remove a portion of the substrate including a bottom portion of at least one first source/drain region of the plurality of source/drain regions, distinct from the second source/drain region, to form at least one etched BC region. The at least one etched BC region is filled with a conductive material. The method enhances device performance by improving electrical isolation and connectivity through the formation of backside partial diffusion breaks and backside contacts.

In embodiments, the method further includes forming at least one BPDB opening and at least one BC opening by creating at least one etching pattern on the backside of the substrate through either the placement of a pattern mask or the use of a self-aligned etching process without the placement of a pattern mask, thus enabling the precise and efficient formation of openings, and enhancing manufacturing flexibility.

In embodiments, the method further includes forming a “counterdoped” region of a different conductivity type as the second source/drain region located along at least a portion of the perimeter of the BPDB region. The effect of the counterdoped region is to create a larger potential barrier between the substrate and the second source/drain region, thus reducing parasitic leakage between the first and second source/drain regions.

In embodiments, the method further includes forming at least one BC region before at least one BPDB region. The sequence provides flexibility in manufacturing options.

In embodiments, the method further comprises forming at least one BPDB region before at least one BC region, also providing a different option in the manufacturing process.

In embodiments, the method includes forming at least one BPDB region by depositing a non-conductive liner on the etched BPDB region and filling it with a conductive material. This can act as a backside gate structure to suppress parasitic leakage while reducing the doping requirement in the substrate.

In embodiments, the method further comprises extending at least one BPDB region into the substrate deeper than at least one BC region is extended into the substrate and alleviating leakage currents between source/drain regions.

In embodiments, the method includes forming at least one BC region by positioning the BC region adjacent to at least one BPDB region, thus facilitating self-alignment with at least one first source/drain region during etching.

In embodiments, the method includes forming a doped region of the same conductivity type as the first source/drain region located along at least a portion of the interface between the BC region and the first source/drain region. The effect of the doped region is two-fold. First, additional dopants at the interface between the BC region and the first source/drain region will reduce contact resistance between the BC region and the first source/drain region. Second, if the doped region also extends along the sidewall of the BC region, then the apparent contact area is increased, thus further reducing contact resistance.

In embodiments, the method further comprises introducing dopants into the BPDB opening of an opposite polarity to the source/drain regions.

In embodiments, the method further comprises introducing dopants into the BC opening of the same polarity as the source/drain regions.

### Example Structure of a Semiconductor Device

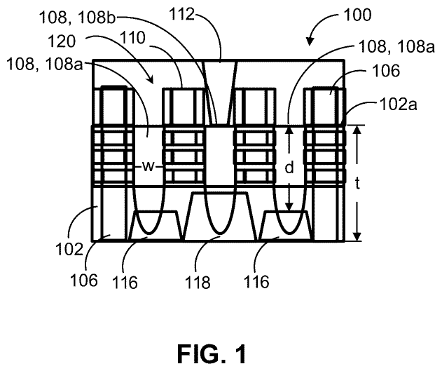

FIG. 1 depicts a cross-sectional view of a semiconductor device 100 that includes a substrate 102 having a frontside 102a and a backside 102b, with a thickness t of the substrate measured from the frontside 102a to the backside 102b. Several source/drain regions 108 are formed in the substrate 102, each extending from the frontside 102a into the substrate 102 to a depth less than the thickness t of the substrate 102. The semiconductor device 100 further includes one or more direct backside contact (DBC) regions 116 (also interchangeably referred to herein as backside contact (BC) regions) extending from the backside 102b into the substrate 102 and electrically connected to one or more first source/drain regions 108a of the several of source/drain regions 108 formed on the substrate 102, providing direct electrical connection between the backside 102b and the one or more first source/drain regions 108a. The semiconductor device 100 further includes one or more backside partial diffusion break (BPDB) regions 118 comprising a non-conductive material, extending from the backside 102b into the substrate 102 and electrically isolating a second source/drain region 108b, distinct from the one or more first source/drain regions 108a, of the source/drain regions 108, from the backside 102b.

In various embodiments disclosed below, the source/drain regions 108 within the substrate 102 may have equal or unequal depths d or widths w, allowing for flexibility in the design of the semiconductor device 100 to meet specific performance requirements. A gate region 110 can be positioned between a pair of source/drain regions 108a, 108b, forming a transistor 120 that controls the flow of current between the source and drain regions.

The DBC regions 116 and BPDB regions 118 are typically formed by etching portions of the substrate 102 from the backside 102b, which allows for precise placement and alignment of the DBC regions 116 and BPDB regions 118 within the structure of the semiconductor device 100.

In some embodiments, forming the DBC region 116 adjacent to the BPDB region 118 within the substrate 102 facilitates self-alignment of the DBC region 116 with a first source/drain region 108a of the plurality of source/drain regions 108 during etching, enhancing manufacturing efficiency and precision.

In some other embodiments, forming the BPDB region 118 adjacent to the DBC region 116 within the substrate 102 facilitates self-alignment of the BPDB region 118 with a second source/drain region 108b of the plurality of source/drain regions 108 during etching, enhancing manufacturing efficiency and precision.

In some embodiments, the BPDB region 118 extends deeper into the substrate 102 than the DBC region 116 to suppress leakage currents between the source/drain regions 108. In some other embodiments, the BPDB region 118 and the DBC region 116 equally extend into the substrate 102. The BPDB region 118 is configured to reduce or prevent parasitic leakage within the substrate 102, thereby improving reliability and performance of the semiconductor device 100 by reducing the risk of unintended electrical connections and leakage currents.

In various other embodiments described below, methods of fabricating the structure of the semiconductor device 100 are disclosed.

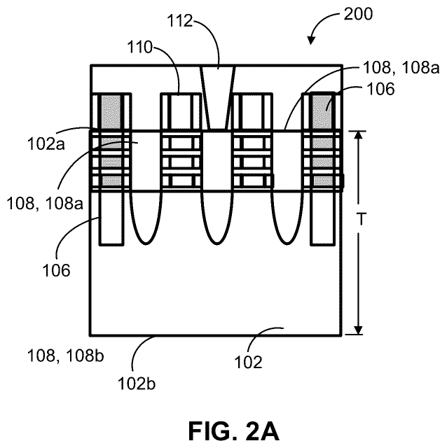

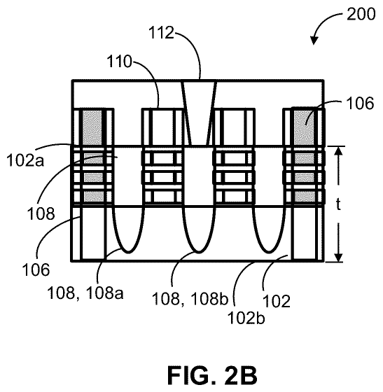

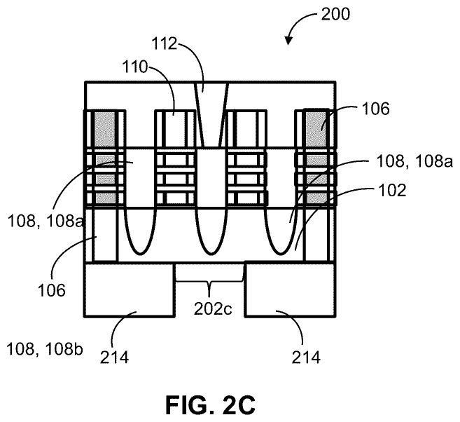

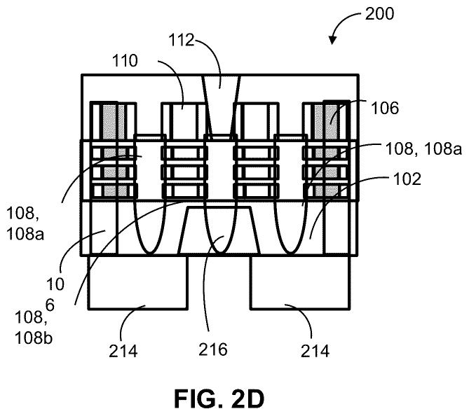

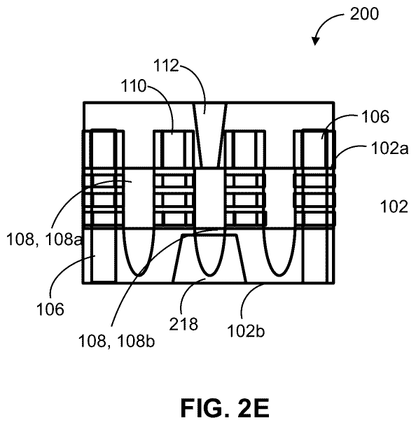

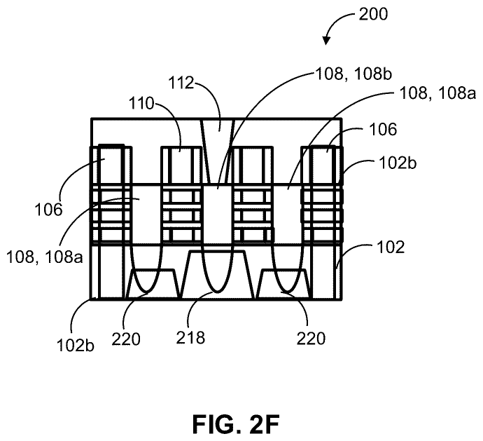

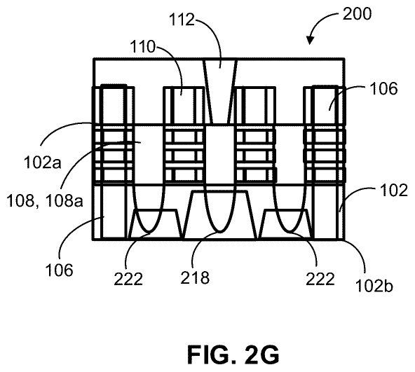

### Embodiment 1 (FIGS. 2A-2G)

FIG. 2A illustrates a cross-sectional view of the semiconductor device 200 showing a plurality of source/drain regions 108. The semiconductor device 200 has a substrate 102 with a frontside 102a or top surface and a backside 102b or bottom surface. The thickness T of the substrate 102 is defined as the distance measured from the frontside 102a to the backside 102b. The substrate 102 includes several source/drain regions 108, which are provided deep in the substrate 102, extending from the frontside 102a into the substrate 102 and passing through to a depth less than the thickness T of the substrate 102. The source/drain regions 108 extending from the frontside 102a typically do not reach the backside 102b of the substrate 102. One or more diffusion breaks 106 are provided on the substrate 102, and may extend from the frontside 102a of the substrate 102 into the substrate 102 to a depth greater than the depth of the source/drain regions 108. The diffusion breaks 106 separate the active source/drain regions 108 to prevent leakage or unintended current paths. The semiconductor device 200 also includes a gate region 110 positioned between a pair of source/drain regions 108a, 108b. A contact structure 112 provided at the frontside 102a of the substrate 102 connects the active source/drain regions 108 for interconnection.

FIG. 2B illustrates a cross-sectional view of the semiconductor device 200 showing the substrate 102 after a thinning process in accordance with an illustrative embodiment. The thickness T of the substrate 102 is reduced by thinning from the backside 102b, reducing the thickness to t (where t<T) and decreasing the overall height of the semiconductor device 200. The reduction in thickness (T−t) assists in forming a backside connection to the semiconductor device 200. The new thickness t may be equal to or less than the depth of the diffusion breaks 106 in the substrate 102, as shown in the illustrations. Alternately, the new thickness t may be greater than the depth of the diffusion breaks 106 in the substrate 102, depending on technology trade-offs made between factors such as well isolation, efficient backside contact formation, heat dissipation, and passive device integration.

FIG. 2C illustrates an etching mask 214 formed on the backside 102b of the substrate 102, in accordance with an illustrative embodiment. The etching mask 214 provided on the backside 102b of the substrate 102, exposes only a portion 202c of the substrate 102 directly below a bottom portion of the second source/drain region 108b of the source/drain regions 108.

FIG. 2D illustrates a cross-sectional view of the semiconductor device 200 showing a backside partial diffusion break (BPDB) opening 216 formed on the backside 102b of the substrate 102 in accordance with an illustrative embodiment. Typically, the portion 202c of the substrate 102 directly below the bottom portion of the second source/drain region 108b is etched away until reaching the bottom portion of the second source/drain region 108b to form the BPDB opening 216. In some instances, the portion 202c of the substrate 102 directly below the bottom portion of the second source/drain region 108b, including the bottom portion of the second source/drain region 108b, is etched away to form the BPDB opening 216 as shown in FIG. 2D.

In some embodiments, dopants may be introduced into the BPDB opening 216, of an opposite polarity to the source/drain regions 108, through processes such as ion implantation or gas phase doping. This would serve to further suppress parasitic leakage between the first source/drain region 108a and the second source/drain region 108b. More specifically, in some embodiments, the DBC region comprises a doped region of the same conductivity type as the first source/drain region located along at least a portion of the interface between the DBC region and the first source/drain region. In further embodiments, the BPDB region comprises a “counterdoped” region of a different conductivity type as the second source/drain region located along at least a portion of the perimeter of the BPDB region.

FIG. 2E illustrates a cross-sectional view of the semiconductor device 200 showing the BPDB opening 216 filled with a non-conductive material, forming the BPDB region 218 in accordance with an illustrative embodiment. After filling the non-conductive material into the BPDB opening 216 to form the BPDB region 218, the backside 102b of the substrate 102 is smoothed by performing a smoothing operation such as chemical mechanical polishing or chemical mechanical planarization (CMP), which helps to clean the backside 102b of the substrate after the non-conductive material deposition.

FIG. 2F illustrates a cross-sectional view of the semiconductor device 200 showing the DBC openings 220 formed on the backside 102b of the substrate 102 through a self-aligned etching process without the use of etching or pattern masks in accordance with an illustrative embodiment. The self-aligned etching process on the backside 102b of the substrate 102 removes portions of the substrate 102 on either side of the BPDB region 218, directly below the bottom portions of the first source/drain regions 108a. Typically, portions of the substrate 102 on either side of the BPDB region 218, directly below the bottom portions of the first source/drain regions 108a, are etched away until reaching the bottom portion of the first source/drain regions 108a to form the DBC openings 220. In some instances, the portions of the substrate 102 directly below the bottom portions of the first source/drain regions 108a, including the bottom portion of the first source/drain regions 108a, are etched away to form the DBC openings 220 as shown in FIG. 2F.

In some embodiments, the depth and/or width or area of the DBC openings 220 formed within the substrate 102 is less than that of the BPDB region 218. Forming the DBC openings 220 adjacent to the BPDB region 218 within the substrate 102 facilitates self-alignment of the DBC openings 220 with the first source/drain regions 108a during etching, enhancing manufacturing efficiency and precision. Furthermore, self-alignment of the DBC openings 220 without the need for “placeholders” under source/drain epitaxial layers further improves the fabrication efficiency and reduces complexity.

In some embodiments, as shown in FIGS. 2E-2G, the BPDB region 218 extends deeper into the substrate 102 than the DBC regions 222, which suppresses leakage currents between the first and second source/drain regions 108a, 108b.

FIG. 2G illustrates a cross-sectional view of the semiconductor device 200 showing a polished backside 102b of the substrate 102 with the DBC openings 220 filled with the conductive material to form the DBC regions 222 in accordance with an illustrative embodiment. After filling the conductive material into the DBC openings 220 to form the DBC regions 222, the backside 102b of the substrate 102 is smoothed by performing a smoothing method such as CMP. In one instance, the conductive material is a metal with low resistance which offers unimpeded flow of electric current through the electrical contact provided at the DBC regions 222 at the backside 102b of the substrate 102.

In some embodiments, dopants may be introduced into DBC openings 220 of the same polarity as the source/drain regions 108. This may happen either before the DBC opening 220 are filled with conductive material, using for example ion implantation or gas phase doping, or after the DBC openings 220 are filled with conductive material, using for example ion implantation. This would serve to reduce the contact resistance between the DBC regions 222 and the first source/drain regions 108a.

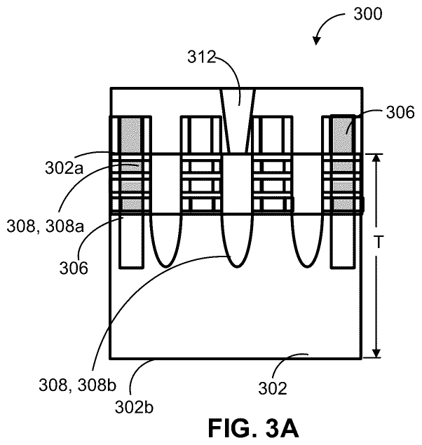

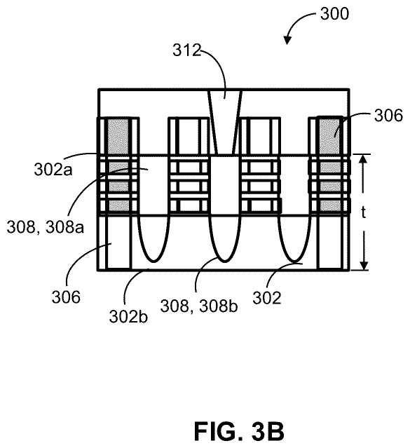

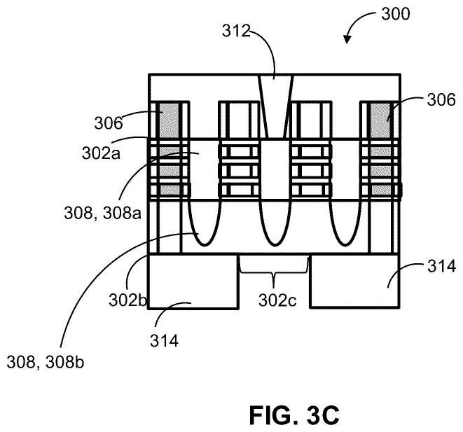

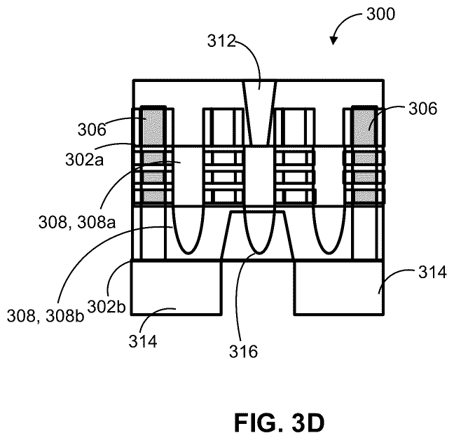

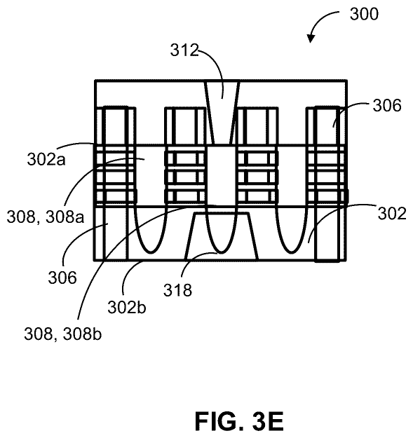

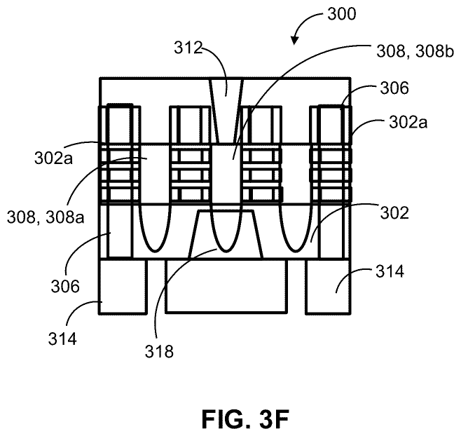

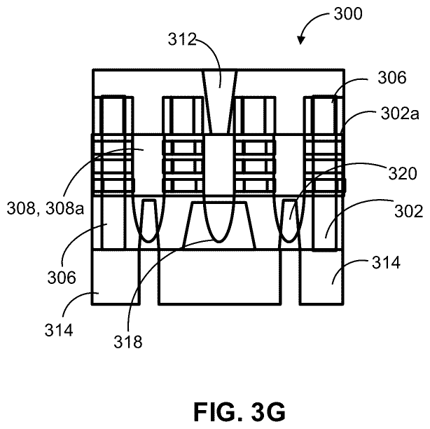

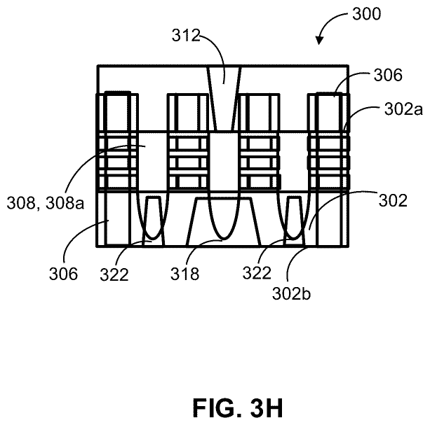

### Embodiment 2 (FIG. 3A-3H)

FIG. 3A illustrates a cross-sectional view of a semiconductor device 300 featuring multiple source/drain regions 308 within a substrate 302. The substrate 302 has a frontside 302a and a backside 302b, with a thickness T defined as the distance from the frontside 302a to the backside 302b. The source/drain regions 308 are formed by doping areas that extend from the frontside 302a into the substrate 302 to depths less than the overall thickness T. A contact structure 312 is provided at the frontside 302a of the substrate 302.

As shown in FIG. 3B, the substrate 302 undergoes a thinning process from the backside 302b, reducing its thickness from T to t (where t<T). The thinning process decreases the overall height of the semiconductor device 300, aiding in device scaling and reducing package size. The new thickness t is typically equal to or less than the depth of any diffusion breaks 306 provided within the substrate 302.

The formation of the backside partial diffusion break (BPDB) region 318 is depicted in FIGS. 3C through 3E. In FIG. 3C, an etching mask 314 is applied to the backside 302b of the substrate 302, exposing only a specific portion 302c directly beneath the second source/drain region 108b.

FIG. 3D shows the substrate 302 after etching the exposed portion 302c to create the BPDB opening 316. The etching process removes material from the backside 302b, extending into the substrate 302 until reaching the bottom of the second source/drain region 308b. In certain instances, the etching may continue into the second source/drain region 308b itself, as illustrated.

In some embodiments, dopants may be introduced into the BPDB opening 316, of an opposite polarity to the source/drain regions 308, through processes such as ion implantation or gas phase doping. This would serve to further suppress parasitic leakage between the first source/drain region 308a and the second source/drain region 308b.

Following the etching step, as shown in FIG. 3E, the BPDB opening 316 is filled with a non-conductive material to form the BPDB region 318. The backside 302b is then smoothed using a technique such as chemical mechanical polishing (CMP) to clean the surface after the deposition of the non-conductive material.

In this embodiment, the DBC regions 322 are formed using an etching mask 314. FIG. 3F illustrates the application of another etching mask 314 to the backside 302b of the substrate 302, which exposes specific areas 302d of the substrate 302 located directly beneath the first source/drain regions 308a.

FIG. 3G depicts the substrate 302 after etching the exposed portions 302d to create the DBC openings 320. The etching process removes material from the backside 302b, extending into the substrate until reaching a bottom portion of the first source/drain regions 308a.

Finally, as illustrated in FIG. 3H, the DBC openings 320 are filled with a conductive material to form the DBC regions 322. The backside 302b is once again smoothed using CMP or a similar method to clean the surface after the conductive material deposition. The conductive material in the DBC regions 322 provides a low-resistance electrical connection between the backside 302b of the substrate 302 and the first source/drain regions 308a, enhancing electrical performance.

In some embodiments, dopants may be introduced into DBC openings 320 of the same polarity as the source/drain regions 308. This may happen either before the DBC opening 320 are filled with conductive material, using for example ion implantation or gas phase doping, or after the DBC openings 320 are filled with conductive material, using for example ion implantation. This would serve to reduce the contact resistance between the DBC regions 322 and the first source/drain regions 308a.

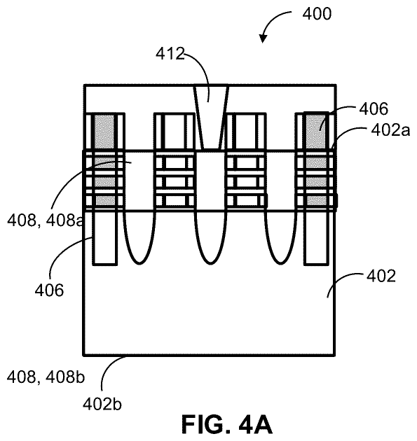

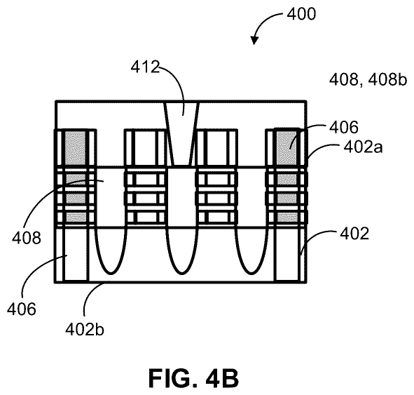

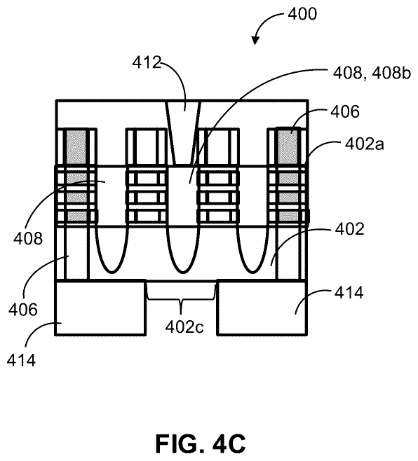

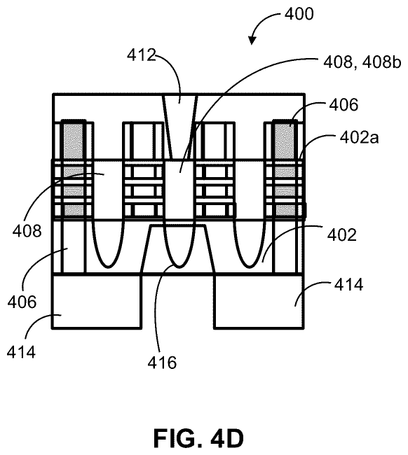

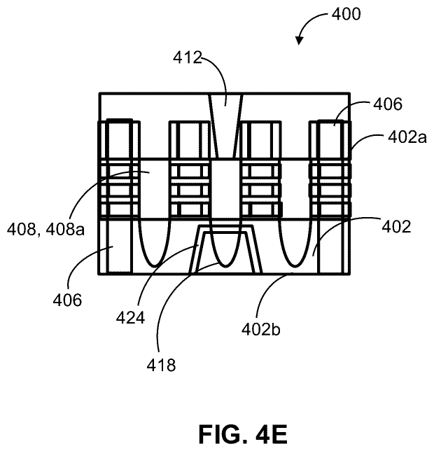

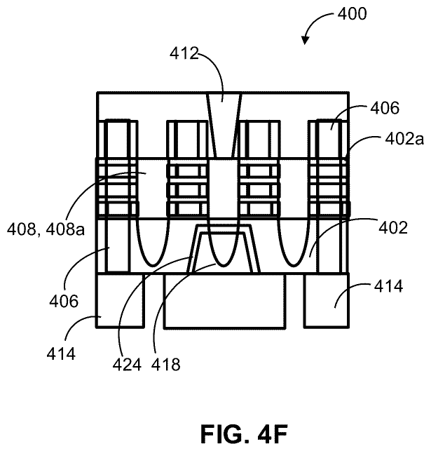

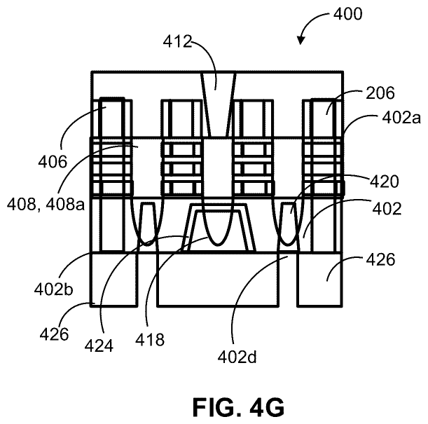

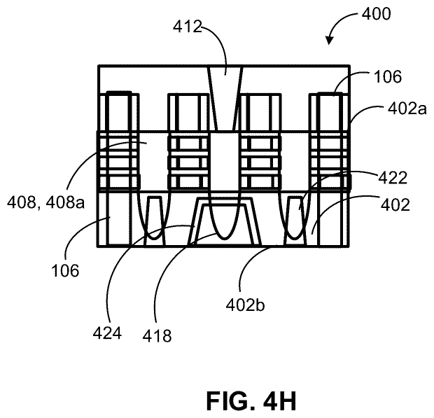

### Embodiment 3 (FIGS. 4A-4H)

Embodiment 3 presents a semiconductor device 400 that incorporates a variation in the formation of the backside partial diffusion break (BPDB) region. FIG. 4A depicts a cross-sectional view of the semiconductor device 400, which includes a substrate 402 with a frontside 402a and a backside 402b. The thickness T of the substrate 402 is measured from the frontside 402a to the backside 402b. Multiple source/drain regions 408 are formed within the substrate 402 by doping areas that extend from the frontside 402a into the substrate to depths less than the overall thickness T. A contact structure 412 is provided at the frontside 402a of the substrate 402.

As illustrated in FIG. 4B, the substrate 402 undergoes a thinning process from the backside 402b, reducing its thickness to t (where t<T), which decreases the overall height of the semiconductor device 400, facilitating device scaling and reducing package size. The new thickness t is typically equal to or less than the depth of any diffusion breaks 406 within the substrate 402.

The formation of the BPDB region in this embodiment involves an additional step compared to previous embodiments. FIG. 4C shows an etching mask 414 applied to the backside 402b of the substrate 402, exposing a specific area 402c directly beneath the second source/drain region 408b.

In FIG. 4D, the substrate 402 is shown after etching the exposed area 402c to create the BPDB opening 416. The etching process removes material from the backside 402b, extending into the substrate 402 until reaching the bottom of the second source/drain region 408b. In some instances, the etching may proceed slightly into the second source/drain region 408b.

In some embodiments, dopants may be introduced into the BPDB opening 416, of an opposite polarity to the source/drain regions 408, through processes such as ion implantation or gas phase doping. This would serve to further suppress parasitic leakage between the first source/drain region 408a and the second source/drain region 408b.

A key factor of the embodiment is the application of a non-conductive liner 424 on the inner surfaces of the BPDB opening 416 before filling it with a conductive material. FIG. 4E illustrates the BPDB opening 416 after the non-conductive liner 424 has been deposited. This non-conductive liner 424, typically made of a dielectric material, enhances electrical isolation and improves the effectiveness of the BPDB region.

Following the deposition of the non-conductive liner 424, the BPDB opening 416 is filled with a conductive material to form the BPDB region 418, as shown in FIG. 4F. The backside 402b is then smoothed using chemical mechanical polishing (CMP) or a similar technique to clean and planarize the surface after the deposition process.

The formation of the direct backside contact (DBC) regions 422 proceeds similarly to previous embodiments, with some variations. FIG. 4G illustrates the application of an etching mask 426 to the backside 402b of the substrate 402, exposing areas 402d directly beneath the first source/drain regions 408a.

FIG. 4H depicts the substrate 402 after etching the exposed areas 402d to create the DBC openings 420. The etching removes material from the backside 402b into the substrate until reaching the bottom of the first source/drain regions 408a. In certain instances, the etching removes material from the backside 402b into the substrate including portions of the bottom of the first source/drain regions 408a such that the depth of the opening from the backside 402b of the substrate is same as the depth of the BPDB opening 416. The DBC openings 420 are then filled with a conductive material to form the DBC regions 422. The backside 402b is once again smoothed using CMP to finalize the surface.

In some embodiments, dopants may be introduced into DBC openings 420 of the same polarity as the source/drain regions 408. This may happen either before the DBC opening 420 are filled with conductive material, using for example ion implantation or gas phase doping, or after the DBC openings 420 are filled with conductive material, using for example ion implantation. This would serve to reduce the contact resistance between the DBC regions 422 and the first source/drain regions 408a.

The inclusion of the non-conductive liner 424 within the BPDB opening 416 in this embodiment acts as a backside gate dielectric to the conductive fill material in in the BPDB region 418, which in this embodiment acts as a backside gate electrode. This enables additional electrostatic suppression of parasitic leakage between the first and second source/drain regions 408a and 408b, respectively, which in turn can reduce the doping requirement in the substrate.

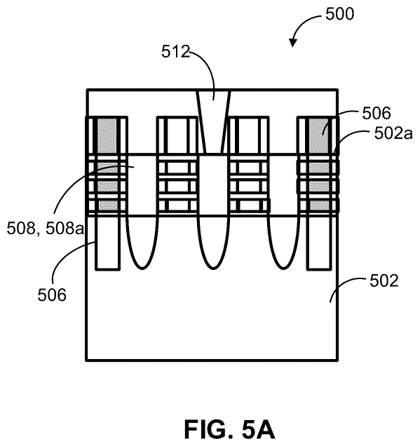

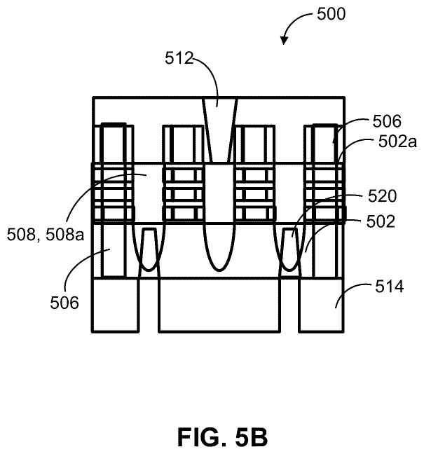

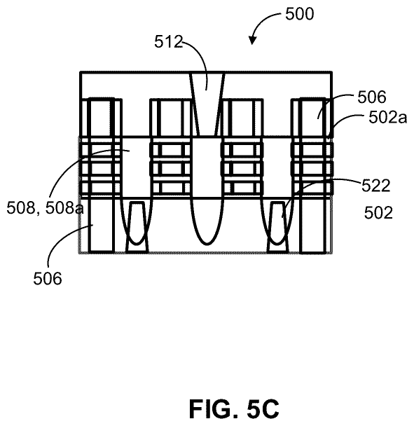

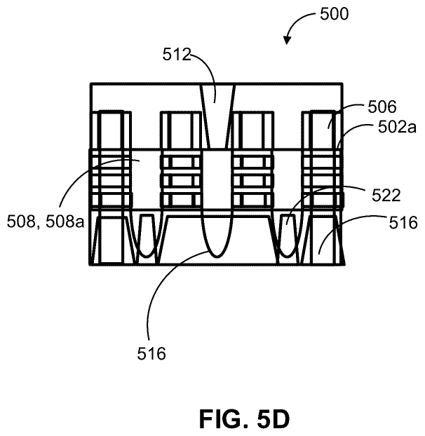

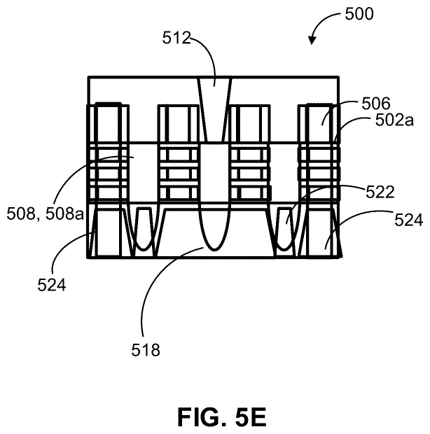

### Embodiment 4 (FIGS. 5A-5E)

Embodiment 4 presents a semiconductor device 500 that features a self-aligned etching process for forming the backside partial diffusion break (BPDB) regions after the formation of direct backside contact (DBC) regions. FIG. 5A illustrates a cross-sectional view of the semiconductor device 500, which includes a substrate 502 with a frontside 502a and a backside 502b. The thickness T of the substrate 502 is measured from the frontside 502a to the backside 502b. Multiple source/drain regions 508 are embedded within the substrate 502, extending from the frontside 502a into the substrate to depths less than the total thickness T. A contact structure 512 is provided at the frontside 502a of the substrate 502.

The substrate 502 undergoes a thinning process from the backside 502b, reducing its thickness to t (where t<T). This reduction in thickness decreases the overall height of the semiconductor device 500, facilitating device scaling and minimizing package size. The new thickness t is typically equal to or less than the depth of any diffusion breaks 506 present within the substrate 502.

In this embodiment, an etching mask 514 is employed to form the DBC regions. FIG. 5B depicts the application of the etching mask 514 to the backside 502b of the substrate 502. This mask exposes specific areas 502d directly beneath the first source/drain regions 508a.

FIG. 5C shows the substrate 502 after the etching process. The etching removes material from the backside 502b, creating the DBC openings 520 beneath the first source/drain regions 508a. The DBC openings 520 are then filled with a conductive material to create the DBC regions 522. The backside 502b is subsequently smoothed using a technique such as chemical mechanical polishing (CMP) to clean and planarize the surface following the deposition process.

In some embodiments, dopants may be introduced into DBC openings 520 of the same polarity as the source/drain regions 508. This may happen either before the DBC opening 520 are filled with conductive material, using for example ion implantation or gas phase doping, or after the DBC openings 520 are filled with conductive material, using for example ion implantation. This would serve to reduce the contact resistance between the DBC regions 522 and the first source/drain regions 508a.

In the next step, as shown in FIG. 5D, the BPDB openings 516 are formed by self-aligned etching of the substrate 502 in areas away from the DBC regions 522. This etching process removes material from the backside 502b, extending through portions of the diffusion breaks 506. Similar to previous embodiments, the etching depths for both the DBC openings 520 and the BPDB openings 516 are the same, resulting in uniform etch depths across the substrate 502.

In some embodiments, dopants may be introduced into the BPDB opening 516, of an opposite polarity to the source/drain regions 508, through processes such as ion implantation or gas phase doping. This would serve to further suppress parasitic leakage between the first source/drain region 508a and the second source/drain region 508b.

After the etching process, as illustrated in FIG. 5E, the BPDB openings 516 are filled with a non-conductive material 524 to form the BPDB regions 518. The backside 502b is again smoothed using CMP or a similar method to finalize the surface. The BPDB regions 518 suppress parasitic leakage between the second source/drain regions 508b and the first source/drain regions 508a.

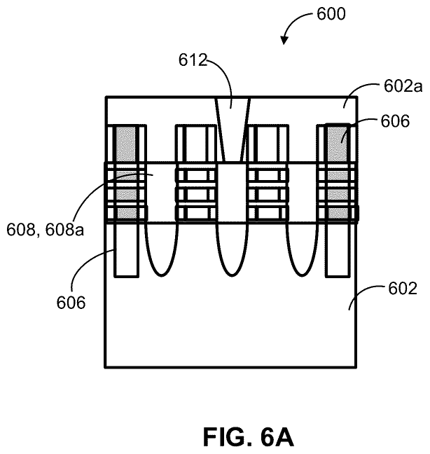

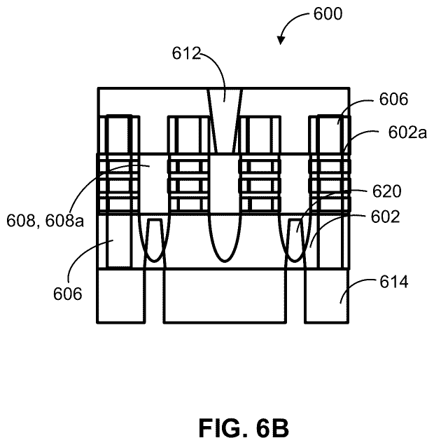

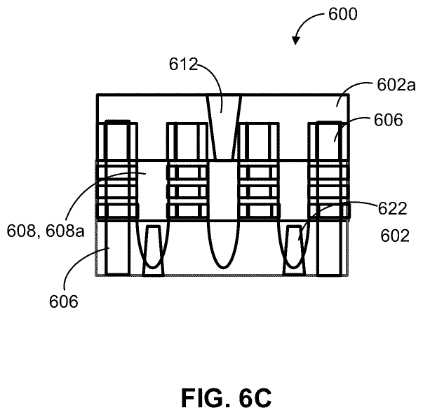

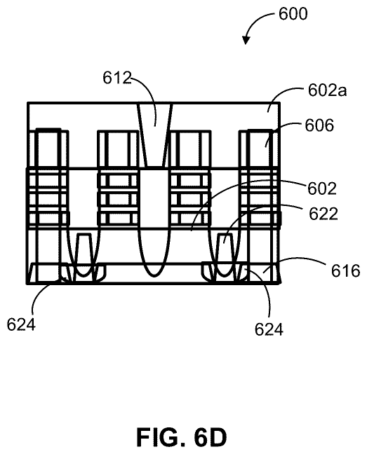

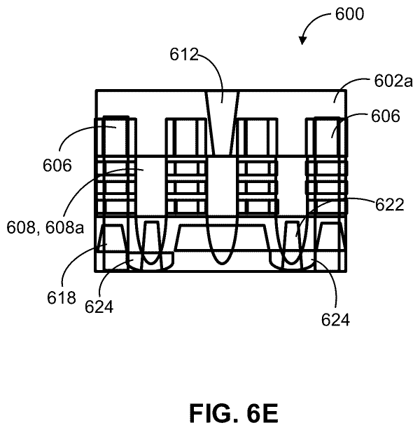

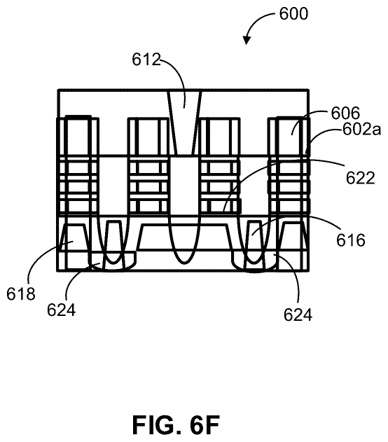

### Embodiment 5 (FIGS. 6A-6F)

Embodiment 5 describes a semiconductor device 600 that incorporates offset spacers below the direct backside contact (DBC) regions to provide additional margin for the connection between the DBC regions and the source/drain epitaxial regions. This embodiment addresses potential misalignment issues that could result in the backside partial diffusion break (BPDB) etch removing portions of the source/drain epitaxial layers along the DBC sidewalls.

FIG. 6A illustrates a cross-sectional view of the semiconductor device 600, which includes a substrate 602 with a frontside 602a and a backside 602b. The thickness T of the substrate 602 is measured from the frontside 602a to the backside 602b. Multiple source/drain regions 608 are embedded within the substrate 602, extending from the frontside 602a into the substrate to depths less than the total thickness T. A contact structure 612 is provided at the frontside 602a of the substrate 602.

The substrate 602 undergoes a thinning process from the backside 602b, reducing its thickness to t (where t<T). This reduction in thickness decreases the overall height of the semiconductor device 600, facilitating device scaling and minimizing package size. The new thickness t is typically equal to or less than the depth of any diffusion breaks 606 provided within the substrate 602.

In this embodiment, an etching mask 614 is applied to the backside 602b of the substrate 602 to define the areas for forming the DBC regions. FIG. 6B shows the application of the etching mask 614, which exposes specific areas 602d directly beneath the first source/drain regions 608a.

In some embodiments, dopants may be introduced into DBC openings 620 of the same polarity as the source/drain regions 608. This may happen either before the DBC opening 620 are filled with conductive material, using for example ion implantation or gas phase doping, or after the DBC openings 620 are filled with conductive material, using for example ion implantation. This would serve to reduce the contact resistance between the DBC regions 622 and the first source/drain regions 608a.

After performing the DBC etching and forming the DBC regions 622 (as shown in FIG. 6C), a partial substrate recess is created, and offset spacers 624 are formed on the DBC sidewalls of the recessed areas, as illustrated in FIG. 6D. The partial substrate recess reduces the thickness of the substrate 602 in the exposed areas 602d, and the offset spacers 630 are deposited beneath the DBC regions 622 and covers the DBC sidewalls. The offset spacers 624, typically made of dielectric material, provide additional margin for the DBC to source/drain epitaxial connections, accommodating potential misalignments during fabrication.

FIG. 6D depicts the substrate 602 after the partial substrate recess and the formation of the offset spacers 624. The recess exposes the bottom portions of the DBC regions 622 filled with conductive material, which are then covered using the offset spacers 624 formed from the bottom. The offset spacers 624 help prevent subsequent etching processes from inadvertently removing portions of the DBC regions 622 or the DBC sidewalls, thus preserving the integrity of the source/drain regions 608.

Following the DBC filling and offset spacer formation, as shown in FIG. 6E, the BPDB openings 616 are formed by self-aligned etching of the substrate 602 in areas away from the DBC regions 622. This etching may extend through portions of the diffusion breaks 606.

In some embodiments, dopants may be introduced into the BPDB opening 616, of an opposite polarity to the source/drain regions 608, through processes such as ion implantation or gas phase doping. This would serve to further suppress parasitic leakage between the first source/drain region 608a and the second source/drain region 608b.

FIG. 6F illustrates the substrate 602 after filling the BPDB openings 616 with a non-conductive material to form the BPDB regions 618. The backside 602b is then smoothed using chemical mechanical polishing (CMP) or a similar method to finalize the surface. The offset spacers 624 remain in place, providing additional insulation and structural support.

The inclusion of offset spacers 624 below the DBC regions 622 in this embodiment provides a margin for DBC to source/drain epitaxial connections in the event of DBC misalignment. This design minimizes the risk of the BPDB etch removing portions of the source/drain epitaxial layers along the DBC sidewalls, enhancing device reliability and performance.

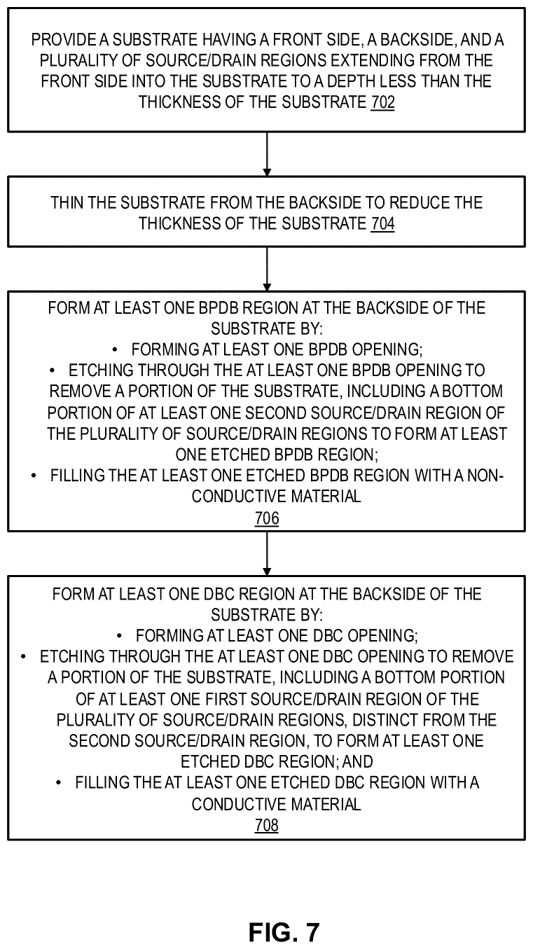

A routine for fabricating a semiconductor device is described, as illustrated in the flowchart of FIG. 7. The routine includes several steps to form the semiconductor device with enhanced electrical connectivity and isolation features.

The routine begins by providing a substrate that has a frontside and a backside, with a thickness measured from the frontside to the backside (block 702). A plurality of source/drain regions are formed in the substrate, each extending from the frontside into the substrate to a depth less than the thickness of the substrate. These source/drain regions serve as terminals for transistors within the semiconductor device.

Next, the substrate is thinned from the backside to reduce its overall thickness (block 704). Thinning decreases the height of the semiconductor device, aiding in device scaling and reducing package size. The new thickness is typically equal to or less than the depth of any diffusion breaks present within the substrate, ensuring structural integrity without exposing the bottom portions of the source/drain regions before the etching steps.

To suppress leakage between source/drain regions, at least one backside partial diffusion break (BPDB) region is formed at the backside of the substrate (block 706), which involves forming at least one BPDB opening on the backside of the substrate. The BPDB opening can be created by forming an etching pattern through methods such as placing a pattern mask, using a self-aligned etching process without a pattern mask, or a combination thereof.

The routine continues by etching through the BPDB opening to remove a portion of the substrate, including the bottom portion of at least one second source/drain region of the plurality of source/drain regions. This forms the etched BPDB region. In some embodiments, the BPDB region is extended deeper into the substrate than the direct backside contact (DBC) region to suppress leakage currents between source/drain regions.

Before filling, a non-conductive liner may be deposited on the etched BPDB region. This liner improves electrical isolation, enhances the structural integrity of the BPDB region, and provides a barrier against unwanted diffusion of materials. The etched BPDB region is then filled with a non-conductive material to complete the BPDB region.

At least one DBC region is formed at the backside of the substrate to provide direct electrical connectivity between the backside and specific source/drain regions, as shown in block 708, This may involve forming at least one DBC opening on the backside of the substrate. Similar to the BPDB opening, the DBC opening can be formed by creating an etching pattern through placing a pattern mask, using a self-aligned etching process without a pattern mask, or a combination thereof. Forming the DBC region may include positioning it adjacent to the BPDB region within the substrate. This arrangement facilitates self-alignment with the first source/drain region during etching, enhancing manufacturing precision without the need for additional alignment steps and reducing fabrication complexity and costs.

The routine proceeds by etching through the DBC opening to remove a portion of the substrate, including the bottom portion of at least one first source/drain region distinct from the second source/drain region. This forms the etched DBC region.

The etched DBC region is then filled with a conductive material to establish a low-resistance electrical connection between the backside of the substrate and the first source/drain region. This conductive filling enhances electrical performance by providing efficient power distribution.

After forming the BPDB and DBC regions, the backside of the substrate is smoothed by performing chemical mechanical polishing (CMP). This step ensures a planar surface for subsequent processing and improves the overall quality of the device.

In certain embodiments, the DBC region is formed before the BPDB region. Forming the DBC region first may simplify alignment processes. Alternatively, the BPDB region may be formed before the DBC region, which may enhance electrical isolation prior to establishing direct contacts, depending on specific fabrication requirements and desired device characteristics.

Creating etching patterns for forming the BPDB and DBC openings can involve placing a pattern mask to define specific areas for etching, using a self-aligned etching process without a pattern mask that relies on existing structures for alignment, or combining both methods to optimize precision and efficiency.

By making the BPDB region deeper than the DBC region, the method helps suppress leakage currents between source/drain regions. It also increases the distance between the top surface of the DBC and the bottom surface of the gate electrode, thus reducing the risk of forming a short-circuit connection between the DBC and the gate electrode.

Thinning the substrate reduces its thickness without exposing the bottom portions of the source/drain regions before the etching steps. This preserves the integrity of the source/drain regions and prevents potential damage during processing.

Depositing a non-conductive liner on the etched BPDB region before filling with the non-conductive material can improve electrical isolation, enhance the structural integrity of the BPDB region, and provide a barrier against unwanted diffusion of materials.

Positioning the DBC region adjacent to the BPDB region facilitates self-alignment with the first source/drain region during etching, enhances manufacturing precision without the need for additional alignment steps, and reduces fabrication complexity and costs.

In one embodiment, the second source/drain region is electrically connected to a metallization layer along the frontside of the substrate. In another embodiment, the DBC region and BPDB region are separated by a non-conducting spacer region along at least a portion of the sidewalls of both the backside contact region and the BPDB region.

In one embodiment, the routine and structures as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device comprising:
a substrate having a frontside and a backside;
a transistor comprising a gate region, a first source/drain region of a first depth into the substrate, and a second source/drain region of a second depth into the substrate;
a backside contact (BC) region extending from the backside into the substrate and electrically connected to the first source/drain region a backside partial diffusion break (BPDB) region comprising a non-conducting material, extending from the backside into the substrate and distinct from the first source/drain region.

2. The semiconductor device of claim 1, wherein the first depth of the first source/drain region is not equal to the second depth of the second source/drain region.

3. The semiconductor device of claim 1, wherein the BPDB region displaces at least a bottom portion of the second source/drain region.

4. The semiconductor device of claim 1, wherein the BPDB region displaces at least a bottom portion of the substrate under the gate region and in between the first and second source/drain regions.

5. The semiconductor device of claim 1, wherein the BC region further comprises a doped region of the same conductivity type as the first source/drain region located along at least a portion of a perimeter of the BC region.

6. The semiconductor device of claim 1, wherein the BPDB region further comprises a counterdoped region of a different conductivity type as the second source/drain region located along at least a portion of a perimeter of the BPDB region.

7. The semiconductor device of claim 1, wherein the BC region is formed adjacent to the BPDB region within the substrate.

8. The semiconductor device of claim 7, wherein the BC region and BPDB region are separated by a non-conducting spacer region along at least a portion of a sidewall of the backside contact region and a portion of a sidewall of the BPDB region.

9. The semiconductor device of claim 1, wherein the BPDB region further comprises a conducting material which is electrically isolated from the substrate and second source/drain region by the non-conducting material.

10. The semiconductor device of claim 1, wherein the BPDB region further comprises at least one additional non-conducting material.

11. The semiconductor device of claim 1, wherein the second source/drain region is electrically connected to a metallization layer along the frontside of the substrate.

12. A method of fabricating a semiconductor device, comprising:
providing a substrate having a frontside, a backside, and a plurality of source/drain regions extending from the frontside into the substrate to a depth less than a thickness of the substrate, the thickness of the substrate being measured from the frontside to the backside;
thinning the substrate from the backside to reduce the thickness of the substrate;
forming at least one backside partial diffusion break (BPDB) region at the backside of the substrate by:
forming at least one BPDB opening;
etching through the at least one BPDB opening to remove a portion of the substrate, including a bottom portion of at least one second source/drain region of the plurality of source/drain regions to form at least one etched BPDB region;
filling the at least one etched BPDB region at least partially with a non-conductive material;
forming at least one backside contact (BC) region at the backside of the substrate by:
forming at least one BC opening;
etching through the at least one BC opening to remove another portion of the substrate, including a bottom portion of at least one first source/drain region of the plurality of source/drain regions, distinct from the second source/drain region, to form at least one etched BC region; and
filling the at least one etched BC region with a conductive material.

13. The method of claim 12, wherein forming the at least one BPDB opening and the at least one BC opening further comprises creating at least one etching pattern on the backside of the substrate by: a placement of a pattern mask or a use of a self-aligned etching process without a placement of a pattern mask.

14. The method of claim 12, further comprising forming a counterdoped region of a different conductivity type as the second source/drain region located along at least a portion of a perimeter of the BPDB region.

15. The method of claim 12, further comprising forming the at least one BC region before the at least one BPDB region.

16. The method of claim 12, further comprising forming the at least one BPDB region before the at least one BC region.

17. The method of claim 12, wherein forming the at least one BPDB region includes depositing a non-conductive liner on the at least one etched BPDB region and filling with another conductive material.

18. The method of claim 12, further comprising extending the at least one BPDB region into the substrate deeper than the at least one BC region is extended into the substrate.

19. The method of claim 12, wherein forming the at least one BC region includes positioning the at least one BC region adjacent to the at least one BPDB region, facilitating self-alignment with the at least one first source/drain region during etching.

20. The method of claim 12, further comprising forming a doped region of a same conductivity type as the first source/drain region located along at least a portion of a perimeter of the BC region.
